(19) United States
(12) Patent Application Publication
(10) Pub. No.: US 2017/0091021 A1
(43) Pub. Date: Mar. 30, 2017

(54) Reduction of Area and Power for Sense Amplifier in Memory

(71) Applicant: Avalanche Technology, Inc., Fremont, CA (US)

(72) Inventors: Ebrahim Abedifard, San Jose, CA (US); Ravishankar Tadepalli, Fremont, CA (US)

(21) Appl. No.: 15/276,318

(22) Filed: Sep. 26, 2016

Related U.S. Application Data
(60) Provisional application No. 62/232,349, filed on Sep. 24, 2015.

(51) Int. Cl. G06F 11/10; G11C 11/16

(52) U.S. Cl. CPC G06F 11/1044; G11C 11/1673

(57) ABSTRACT

The present invention is directed to a memory subsystem including a plurality of memory banks, each of the memory banks including a plurality of memory cells arranged in rows and columns with word-lines connecting to the memory cells along a row direction and bit-lines connecting to the memory cells along a column direction; a sense amplifier module shared by the plurality of memory banks, the sense amplifier module including a plurality of sense amplifiers for sensing resistance of the memory cells; a plurality of memory buffer modules coupled to the sense amplifier module, each of the memory buffer modules including a plurality of memory buffers for storing data from the sense amplifiers; and an input/output (I/O) interface coupled to the memory buffer modules.

### CROSS REFERENCE TO RELATED APPLICATIONS

The present application claims the benefit of the provisional application bearing Ser. No. 62/232,349 filed on Sep. 24, 2015, entitled “Method and Apparatus to Reduce Area and Power for Sense Amplifier in a Memory.”

### BACKGROUND OF THE INVENTION

Field of the Invention

The present invention relates to reduction of area and power in a memory component by sharing a common sense amplifier module across various memory banks.

Description of the Prior Art

In a typical memory component with multiple memory banks, each of the memory banks interface to a dedicated sense amplifier module, row decoder and column decoder to provide simultaneous access to multiple memory banks. Each of the memory banks includes a plurality of memory cells arranged in rows and columns with word-lines connecting to the memory cells along the row direction and bit-lines connecting to the memory cells along the column direction. The power consumption of the memory component increases with the number of active banks and hence limits the number of active banks in a predefined timing window. In some implementations, the sense amplifier module occupies a sizeable area compared with the memory bank and thus becomes overhead for the memory component. In some implementations, owing to the access patterns from the memory component controller, there is significant context switching between the memory banks, thereby incurring significant overhead on the timing interface to host CPU due to activation, reading and pre-charging of rows within a memory bank. In some implementations, the design of the sense amplifier module may be optimized by lowering noise tolerance limits and/or lowering the speed of operation to attain a smaller size.

### SUMMARY OF THE INVENTION

The present invention is directed to a memory subsystem including a plurality of memory banks, each of the memory banks including a plurality of memory cells arranged in rows and columns with word-lines connecting to the memory cells along a row direction and bit-lines connecting to the memory cells along a column direction; a sense amplifier module shared by the plurality of memory banks, the sense amplifier module including a plurality of sense amplifiers for sensing resistance of the memory cells; a plurality of memory buffer modules coupled to the sense amplifier module, each of the memory buffer modules including a plurality of memory buffers for storing data from the sense amplifiers; and an input/output (I/O) interface coupled to the memory buffer modules.

According to another aspect of the present invention, a memory subsystem includes a plurality of memory banks, each of the memory banks including a plurality of memory cells arranged in rows and columns with word-lines connecting to the memory cells along a row direction and bit-lines connecting to the memory cells along a column direction; a sense amplifier module shared by the plurality of memory banks, the sense amplifier module including an error correction code (ECC) decoder and a plurality of sense amplifiers for sensing resistance of the memory cells; a post processor coupled to the sense amplifier module for further processing of decoded data from the sense amplifier module; and a plurality of memory buffer modules coupled to the post processor, each of the memory buffer modules including a plurality of memory buffers for storing data from the sense amplifiers.

Several advantages of the various embodiments of the present invention are evident to those skilled in the art after having read the following detailed description of the embodiments illustrated in the several figures of the drawing. The invention described in the following figures can be extended to memory component architectures with multiple groups of memory banks on various interfaces including but not limited dual data rate (DDR) interface and various implementations of asymmetric timing in various stages between input/output interface and the memory banks.

The requirement is a scheme for reducing semiconductor area and power consumption and sensing very low range differential signals in a multi-bank memory component.

### IN THE DRAWINGS

FIG. 1 is a block diagram illustrating a conventional memory subsystem and components thereof.

FIG. 2 is a block diagram illustrating a memory subsystem in accordance with an embodiment of the present invention.

FIG. 3 is a schematic diagram showing an array of memory cells with each cell including a memory element and a selection transistor coupled in series.

FIG. 4 is a schematic diagram showing an array of memory cells with each cell including a memory element and a two-terminal selector coupled in series.

FIG. 5 shows TABLE 1 that compares sizes of a conventional memory subsystem and a memory subsystem in accordance with an embodiment of the present invention.

FIG. 6 is a block diagram illustrating a memory subsystem in accordance with another embodiment of the present invention.

FIG. 7 is a block diagram illustrating communication between a memory controller and a memory component via a set of signals.

FIG. 8 shows a timing diagram that illustrates timing relationship between various signals for activation of multiple memory banks.

FIG. 9 shows a timing diagram that illustrates timing relationship between various signals for reading data in one memory bank while activating other memory banks.

### DETAILED DESCRIPTION OF VARIOUS EMBODIMENTS

In the following description of the embodiments, reference is made to the accompanying drawings that form a part hereof, and in which is shown by way of illustration of the specific embodiments in which the invention may be practiced. It is to be understood that other embodiments may be utilized because structural changes may be made without departing from the scope of the present invention. It should be noted that the figures discussed herein are not drawn to scale and thicknesses of lines are not indicative of actual sizes.

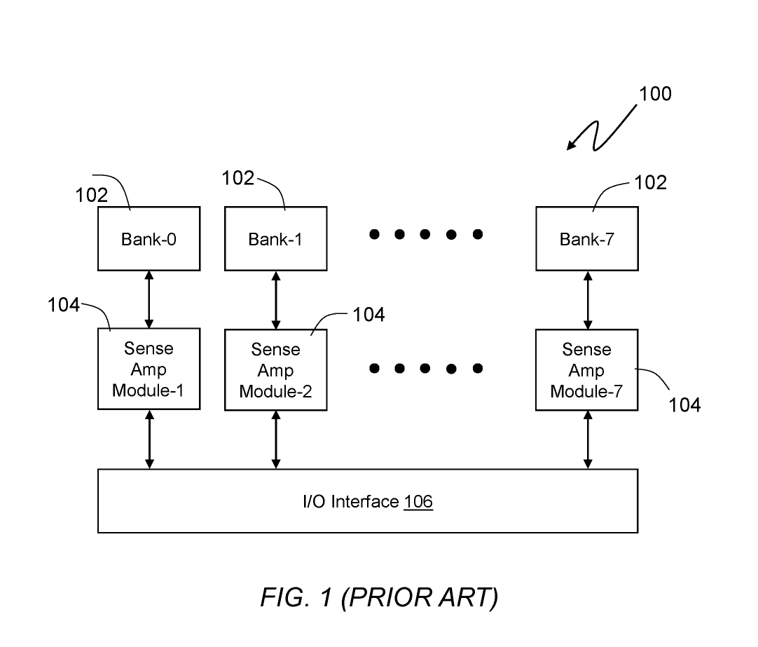

FIG. 1 shows a memory subsystem 100 of a conventional memory component having a double data rate (DDR) interface. The memory subsystem 100 includes a set of memory banks 102, each of which being coupled to a dedicated sense amplifier module 104 used for sensing the data stored therein. The sense amplifier module 104 includes a plurality of sense amplifiers, each of which may sense either voltage or current for each bit-line from a respective one of the memory banks 102, amplify voltage or current, decode the data stored in the respective memory bank 102 to either a logic level “1” or logic level “0” and for transferring to an input/output (I/O) interface controller 106. A sense amplifier circuit may be repeated “N” times to operate on “N” bit-lines from the memory bank 102 to form a sense amplifier module 104. Alternatively, a sense amplifier may be coupled to two bit-lines from a memory bank, such as in the case of dynamic random access memory (DRAM). The size of the sense amplifier depends on various factors, such as but not limited to the number of bit-lines from each memory bank 102, speed of operation, implementation like voltage based sensing circuit or current based sensing circuit, amount of noise sensitivity to distinguish between noise and signal levels. Since the sense amplifier module 104 is repeated for each memory bank 102, the sense amplifier modules 104 occupy a significant proportion of the memory subsystem 100.

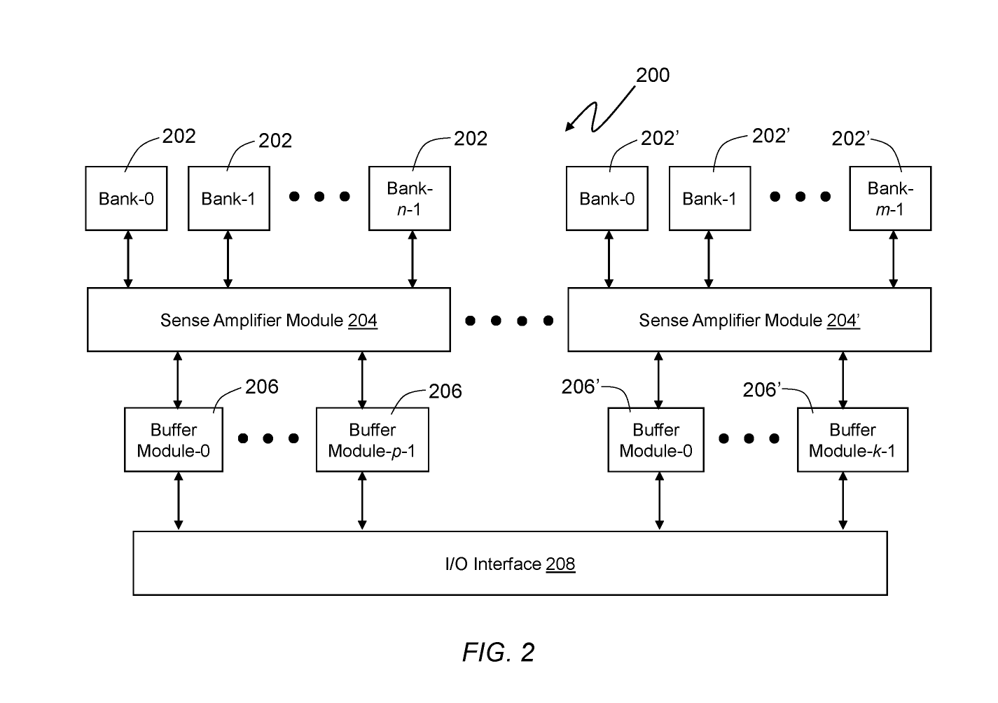

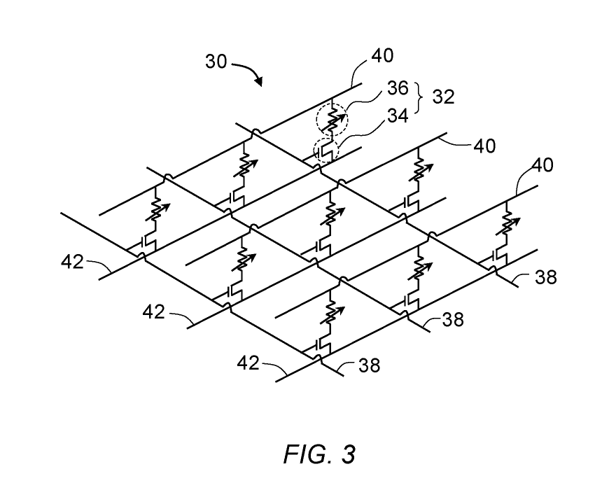

Now referring to FIG. 2, a memory subsystem 200 including a plurality of memory banks 202 is shown in accordance with an embodiment of the present invention. Each memory bank 202 may include a plurality of memory cells arranged in rows and columns with word-lines connecting to the memory cells along the row direction and bit-lines connecting to the memory cells along the column direction. FIG. 3 shows a schematic diagram for an exemplary memory cell array 30, which comprises a plurality of memory cells 32 with each of the memory cells 32 including a selection transistor 34 coupled to a memory element 36 in series; a plurality of parallel word lines 38 with each being coupled to the gates of a respective row of the selection transistors 34 along the row direction; and a plurality of parallel bit lines 40 with each being coupled to a respective column of the memory elements 36 along the column direction; and a plurality of parallel source lines 42 with each being coupled to a respective row or column of the selection transistors 34. Each of the memory banks 202 may include 16, 32, 64, 128, 256 or any suitable number of bit-lines. While FIG. 3 shows the memory cell array 30 has a square array arrangement, i.e. the word-lines 38 and bit-lines 40 extend along the close-packed directions of the memory cells 32, the present invention may alternatively use a diamond array arrangement, in which the word-lines and bit-lines extend along directions that are rotated 45° with respect to the close-packed directions of the memory cells 32.

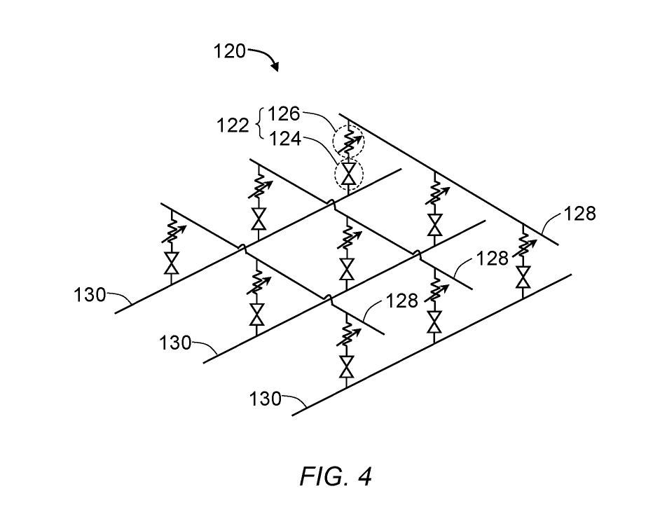

FIG. 4 shows a schematic diagram for another exemplary memory cell array 120 that may be used in the memory banks 202 of the present invention. The memory cell array 120 comprises a plurality of memory cells 122 with each of the memory cells 122 including a bi-directional two-terminal selector element 124, such as but not limited to Ovonic threshold switch (OTS), coupled to a memory element 126 in series; a plurality of parallel first wiring lines 128 with each being coupled to a respective row of the memory elements 126 in a first direction; and a plurality of parallel second wiring lines 130 with each being coupled to a respective row of the selection elements 124 in a second direction substantially perpendicular to the first direction. Accordingly, the memory cells 122 are located at the cross points between the first and second wiring lines 128 and 130. The first and second wiring lines 128 and 130 may be the word-lines and bit-lines, respectively, or vice versa.

The memory elements 36 and 126 may change the resistance state thereof by any suitable switching mechanism, such as but not limited to phase change, precipitate bridging, magnetoresistive switching, or any combination thereof. In one embodiment, the memory elements 36 and 126 comprise a phase change chalcogenide compound, such as but not limited to Ge₂Sb₂Te₅ or AgInSbTe, which can switch between a resistive phase and a conductive phase. In another embodiment, the memory elements 36 and 126 comprise a nominally insulating metal oxide material, such as but not limited to NiO, TiO₂, HfO₂, Ta₂O₅, or Sr(Zr)TiO₃, which can switch to a lower electrical resistance state as metal rich precipitates grow and link to form conductive paths upon application of an appropriate voltage. In still another embodiment, the memory elements 36 and 126 comprise a magnetic free layer and a magnetic reference layer with an insulating electron tunnel junction layer interposed therebetween, collectively forming a magnetic tunnel junction (MTJ). When a switching current is applied, the magnetic free layer would switch the magnetization direction thereof, thereby changing the electrical resistance of the MTJ. The magnetic free layer may have a variable magnetization direction substantially perpendicular to a layer plane thereof. The magnetic reference layer may have a fixed magnetization direction substantially perpendicular to a layer plane thereof. Alternatively, the magnetization directions of the magnetic free and reference layers may have orientations that are substantially parallel to layer planes thereof.

With continuing reference to FIG. 2, a plurality of memory banks 202 numbered from “0” to “n−1” share a sense amplifier module 204, thereby reducing the total occupied area of the sense amplifier circuitry. The sense amplifier module 204 may sense a row of memory cells in one of the memory banks 202 at a time. The output from the sense amplifier module 204 is transferred to a plurality of buffer modules 206 numbered from “0” to “p−1” and then onto an I/O interface 208. The size of each of the buffer modules 206 depends on the number of bit-lines from each memory bank 202 as sensed by the sense amplifier module 204 and the memory technology, such as but not limited to a single level memory cell storing 1 bit of information or multi-level cell storing multiple bits of information. In an embodiment, each of the buffer modules 206 includes a plurality of buffers made of flip-flop or latch. In another embodiment, each of the buffer modules 206 includes a plurality of buffers with each buffer storing multiple bits of data and operate in a first-in, first-out (FIFO) queuing mode. The number of buffer modules depends on the memory type with support for multiple channels of data to the I/O interface 208 and the number of banks actively accessed from the I/O Interface 208. In an embodiment, the number of sense amplifiers in the sense amplifier module 204 and the number of buffers in each of the buffer modules 206 are the same. Each sense amplifier may be coupled to a respective one of the buffers in one of the buffer modules 206 at a given time. In another embodiment, the number of bit-lines in each of the memory banks 202 is same as the number of sense amplifiers in the sense amplifier module 204. In this case, each of the bit-lines in one of the memory banks 202 may be connected to a respective sense amplifier in the sense amplifier module 204 at a given time. In still another embodiment, the number of bit-lines in each of the memory banks 202 is twice as many as the number of sense amplifiers in the sense amplifier module 204. In yet another embodiment, the number of columns of memory cells in each of the memory banks 202 is same as the number of sense amplifiers in the sense amplifier module 204. In still yet another embodiment, the number of columns of memory cells in each of the memory banks 202 is twice as many as the number of sense amplifiers in the sense amplifier module 204.

The memory subsystem 200 may further include one or more additional sets of memory banks connected to the I/O interface 208, such as a set of memory banks 202′ numbered from “0” to “m−1” shown. Like the set of memory banks 202, the set of memory banks 202′ share another sense amplifier module 204′, which contains a plurality of sense amplifiers connected to a plurality of buffer modules 206′ that output to the I/O interface 208. Moreover, each set of the additional sets of memory banks (not shown) have analogous configuration and are connected to analogous components as described above. In an embodiment, all sets of memory banks, including the sets of memory banks 202 and 202′, in the memory subsystem 200 have the same number of memory banks. In another embodiment, all sense amplifier modules, including the sense amplifier modules 204 and 204′, contain the same number of sense amplifiers.

In an embodiment, the memory subsystem 200 is compliant with at least one version of low power double data rate (LPDDR) specification or at least one version of double data rate synchronous dynamic random access memory (DDR SDRAM) specification known in the art or to be developed in the future, such as but not limited to LPDDR2, LPDDR3, LPDDR4, DDR SDRAM, DDR2 SDRAM, DDR3 SDRAM, or DDR4 SDRAM.

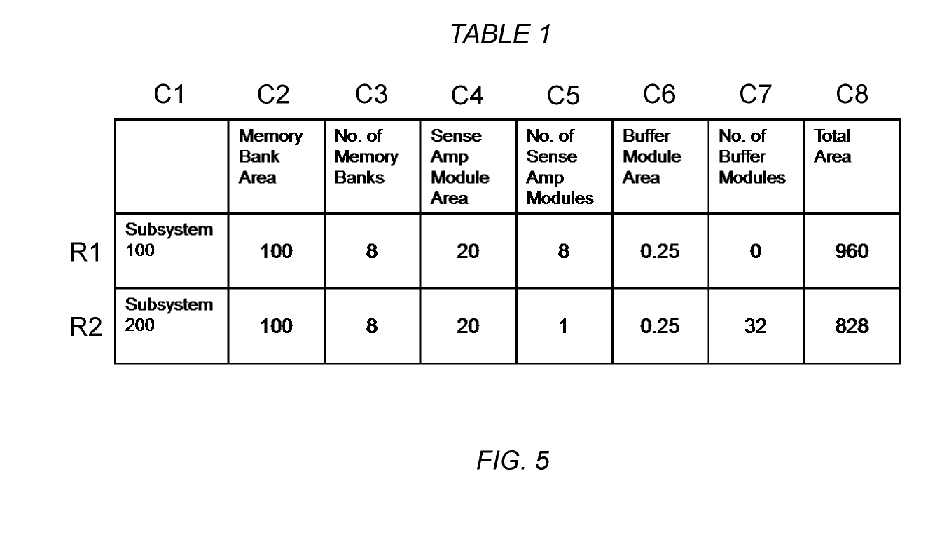

Table 1 shown in FIG. 5 compares the occupied areas of the memory subsystems 100 and 200 when both have 8 memory banks therein. Rows R1 and R2 list areas occupied by various components of the memory subsystems 100 and 200, respectively. Each of the subsystems 100 and 200 has 8 memory banks as indicated in column C3 with each memory bank in both subsystems 100 and 200 occupies a normalized area of 100 as indicated in column C2. Each sense amplifier module in both subsystems 100 and 200 occupies a normalized area of 20 as indicated in column C4. The memory subsystem 100 has 8 sense amplifier modules corresponding to 8 memory banks, while the memory subsystem 200 has only one sense amplifier modules shared by 8 memory banks as indicated in column C5. Columns C6 and C7 indicate that the memory subsystem 200 has 32 buffer modules with each occupying a normalized area of 0.25 while the memory subsystem 100 does not include any buffer. Based on the above-described configurations, the memory subsystems 100 and 200 occupy normalized total areas of 960 and 828, respectively, as indicated in column C8.

In the above example, the memory subsystem 200 utilizes 14% less area than the memory subsystem 100 while providing similar functionality of accessing multiple memory banks, similar or lower power consumption, and comparable data rate to the I/O interface. It should be noted that the areal saving of the memory subsystem 200 increases with increasing number of memory banks since all memory banks share only one sense amplifier module. The smaller size of the memory subsystem 200 may translate to more memory devices per wafer and hence lower cost. The space saved may also be used for additional memory banks, and/or a larger, more complex sense amplifier module for sensing high density memory cells, and/or more buffers to reduce switching activity between memory banks from the memory component controller.

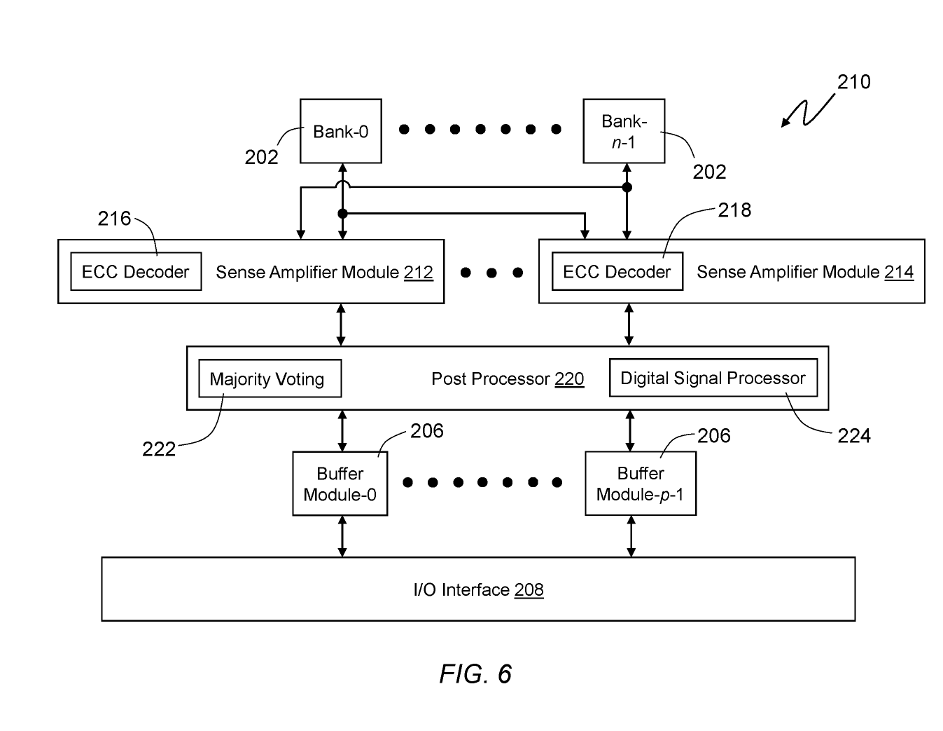

FIG. 6 is a block diagram representing a memory subsystem 210 for a memory component in accordance with another embodiment of the present invention. The memory subsystem 210 includes a set of n memory banks 202 numbered from “0” to “n−1”. Each of the memory banks 202 is connected to one or more of a plurality of sense amplifier modules represented by modules 212 and 214. The sense amplifier modules 212 and 214 may optionally include error correction code (ECC) decoders 216 and 218, respectively. Each of the sense amplifier modules 212 and 214 may have different characteristics and/or different reference inputs providing a better noise immunity to differentiate between signal levels that may be indistinguishable with using a single amplifier module 204 in the memory subsystem 200.

With continuing reference to FIG. 6, the sense amplifier modules 212 and 214 are connected to a post processor 220, which may optionally include functionalities like majority voting 222 and digital signal processor 224. The post processor 220 receives decoded data from the sense amplifier modules 212 and 214 for further processing. The post processing of the decoded data from the sense amplifier modules 212 and 214 by the post processor 220 may further reduce the number of erroneously decoded data bits from the memory banks 202 by the sense amplifiers modules 212 and 214. The post-processed data is stored in a set of p buffer modules 206 numbered from “0” to “p−1,” which are connected to the post processor 220, and is then transmitted to the I/O interface 208.

In an embodiment, the number of sense amplifiers in each of the sense amplifier modules 212 and 214 and the number of buffers in each of the buffer modules 206 are the same. In another embodiment, the number of bit-lines in each of the memory banks 202 is same as the number of sense amplifiers in each of the sense amplifier modules 212 and 214. In still another embodiment, the number of bit-lines in each of the memory banks 202 is twice as many as the number of sense amplifiers in each of the sense amplifier modules 212 and 214. In yet another embodiment, the number of columns of memory cells in each of the memory banks 202 is same as the number of sense amplifiers in each of the sense amplifier modules 212 and 214. In still yet another embodiment, the number of columns of memory cells in each of the memory banks 202 is twice as many as the number of sense amplifiers in each of the sense amplifier modules 212 and 214.

In an embodiment, the memory subsystem 210 is compliant with at least one version of low power double data rate (LPDDR) specification or at least one version of double data rate synchronous dynamic random access memory (DDR SDRAM) specification known in the art or to be developed in the future, such as but not limited to LPDDR2, LPDDR3, LPDDR4, DDR SDRAM, DDR2 SDRAM, DDR3 SDRAM, or DDR4 SDRAM.

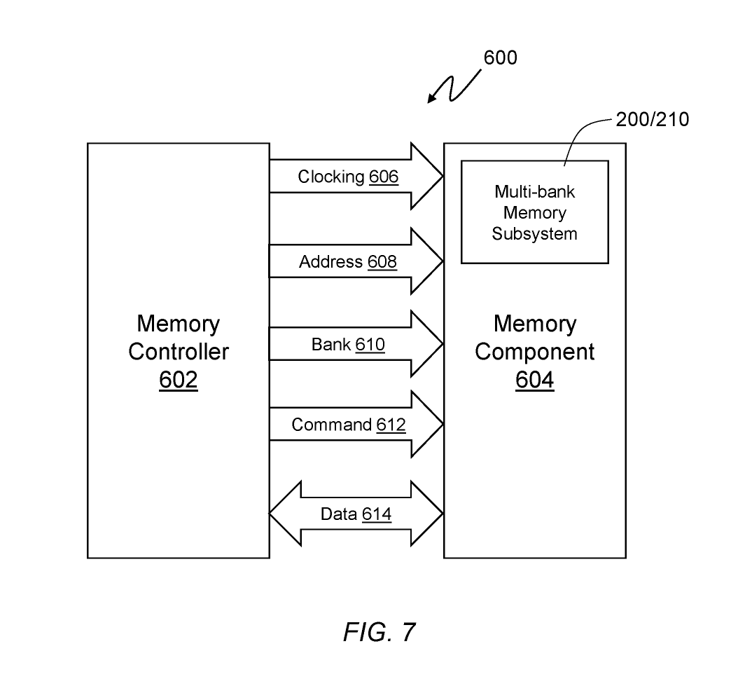

FIG. 7 is a block diagram illustrating an electronic system 600 in accordance with an embodiment of the present invention. The electronic system 600 includes a memory controller 602 interfacing with a memory component 604 incorporating therein the multi-bank memory subsystem 200 or 210. The memory controller 602 interfaces to the memory component 604 based on different sets of signals 606-614. Signal set 606 is used for clocking and synchronization between the memory controller 602 and the memory component 604. Signal set 608 provides row address to a memory bank 202 and column address to a buffer 206 in the memory subsystem 200/210. Signal set 610 provides bank address to select one of the memory banks 202. Signal set 612 provides command information required to transfer data between the memory controller 602 and the memory component 604. Signal set 614 is used to transfer data between the memory component 604 and the memory controller 602.

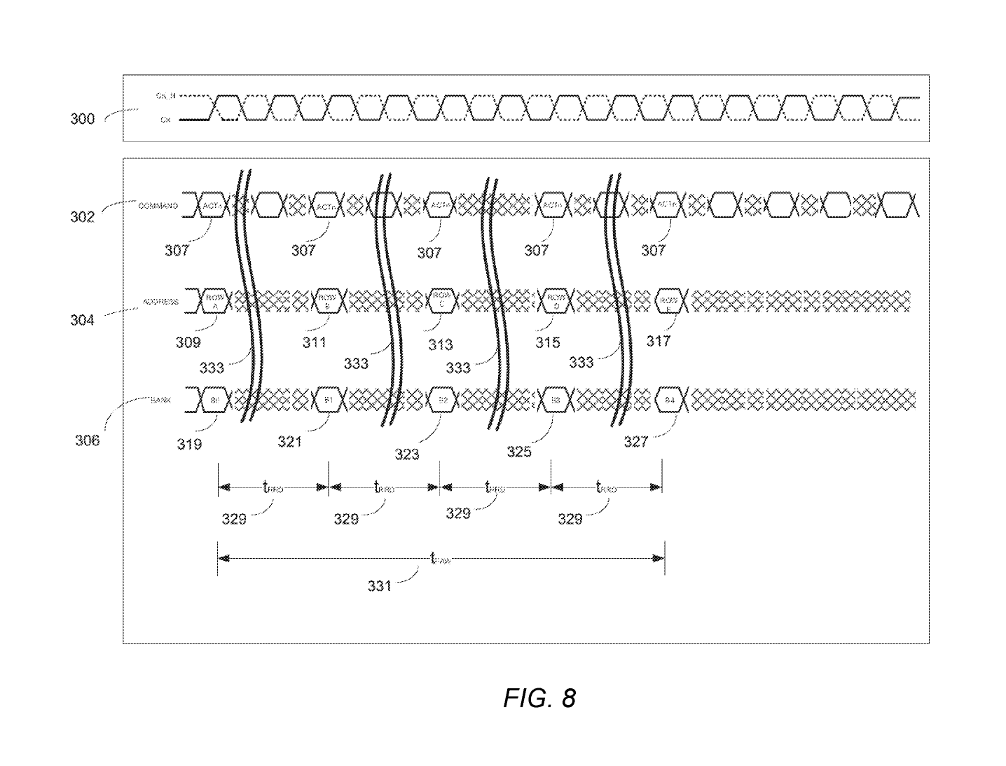

Now referring to FIG. 8, a timing diagram is further shown to illustrate timing relationship between various signals sets 606-614 for activation of multiple memory banks 202. Timing element 300 refers to the clocking information. Timing element 302 indicates timing of activation commands 307. Timing element 304 indicates timing for various row addresses 309,311,313,315,317 into any of the memory banks 202. Timing element 306 indicates timing for bank selection addresses 319,321,323,325 and 327. Timing element 329 indicates the timing interval requirements of the memory component 604 between two successive activation commands 307. Timing element 331 indicates a timing interval wherein only few of the total banks can be activated. Timing element 333 is shown to include a timing break and is for illustration purposes. For example, the timing elements 329 and 331 for a memory component 604 based on a dual data rate (DDR) interface are 7 clock periods and 38 clock periods, respectively, with a clock period being the difference in time between successive rising edges for the signal CK of the timing element 300. For a typical memory component 604 based on the conventional multi-bank memory subsystem 100 shown in FIG. 1 with 8 memory banks 102, only 4 banks are active in the timing window 331. The memory controller 602 cannot activate another memory bank 102 for 10 clock periods. This idle time is advantageously used in accordance with an embodiment of the present invention to increase the time between activation of two memory banks 202, modify the memory subsystem 200 to share a sense amplifier module 204 across multiple memory banks 202, and store the sensed and decoded data from the sense amplifier module 204 to the buffers 206. Based on the timing elements 329 and 331, it is apparent to those skilled in the art that the timing interval t_{RRD} 329 can be extended to a value equivalent to the timing interval t_{FAW} 331 divided by maximum number of banks 202 that can be active in the timing interval t_{FAW} 331. This relationship between timing interval t_{RRD} 329 and timing interval t_{FAW} 331 can be expressed as

t_{RRD}≦t_{FAW}/(maximum active banks 202) (1)

where t_{RRD} 329 is the timing parameter for active to active command and can be as large as quotient of t_{FAW}, which is the timing parameter indicating window for allowable active memory banks, divided by the allowable active memory banks.

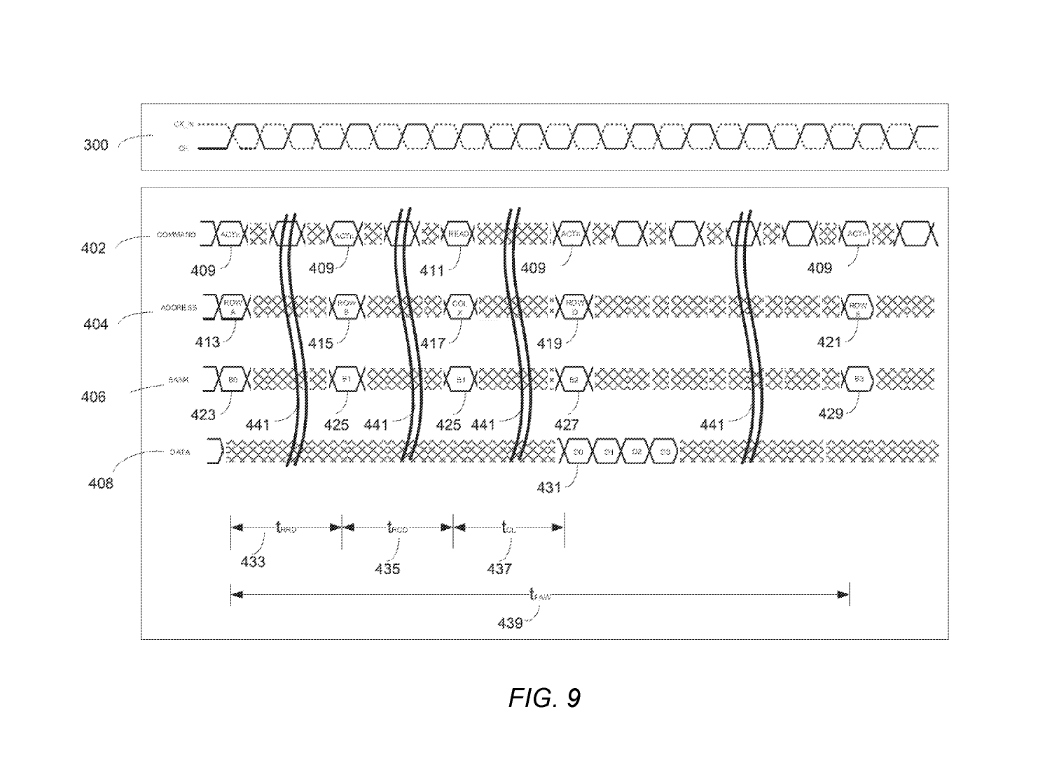

Now referring to FIG. 9, a timing diagram is further shown to illustrate timing relationship between various signals sets 606-614 for reading data in one of the memory banks 202 while activating other memory banks 202. Timing element 300 refers to the clocking information. Timing element 402 indicates timing for activation commands 409 and a read command 411. Timing element 404 indicates timing for various row addresses 413, 415, 419 and 421 into any of the memory banks 202, and a column address 417 into any of the buffers 206. Timing element 406 indicates timing for bank selection addresses 423, 425, 427 and 429. Timing element 408 indicates timing 431 for availability of data to the memory controller 602. Timing element 433 indicates the timing interval requirements of a memory component 604 between two successive activation commands 409. Timing interval 435 indicates timing interval requirements of a memory component 604 between an activation command 409 and a read command 411. Timing element 437 indicates timing interval requirements of a memory component 604 between a read command 411 and the availability of data 431. In accordance with an embodiment of the present invention, the multi-bank memory subsystem 200/210 is designed with a restriction that the timing interval t_{RRD} 433 is less than or equal to the timing interval t_{RCD} 435, which can be expressed as

t_{RRD}≦t_{RCD} (2)

so as not to have an adverse effect on the system performance.

By designing the memory subsystems 200 and 210 with multiple memory banks 202 sharing one or more common sense amplifiers in accordance with equations 1 and 2 and in accordance with the embodiments illustrated in FIGS. 2 and 3, a low cost, low power and high density memory component is realized.

In reference to FIGS. 2 and 3, by incorporating multiple buffer modules 206 per memory bank 202, the number of commands required to activate memory banks 202 is reduced, which translates to reduced activity between the memory banks 202 and the sense amplifier module 204 and between the sense amplifier module 204 and the buffer modules 206. This reduction in the number of commands from the memory component controller 602 to the memory component 604 results in lower power consumption.

Although the invention has been described in terms of specific embodiments, it is anticipated that alterations and modifications thereof will no doubt become apparent to those more skilled in the art. It is therefore intended that the following claims be interpreted as covering all such alterations and modification as fall within the true spirit and scope of the invention.

What is claimed is:

1. A memory subsystem comprising:
a plurality of memory banks, each of the memory banks including a plurality of memory cells arranged in rows and columns with word-lines connecting to the memory cells along a row direction and bit-lines connecting to the memory cells along a column direction;
a sense amplifier module shared by the plurality of memory banks, the sense amplifier module including a plurality of sense amplifiers for sensing resistance of the memory cells; and
a plurality of memory buffer modules coupled to the sense amplifier module, each of the memory buffer modules including a plurality of memory buffers for storing data from the sense amplifiers.

2. The memory system of claim 1 further comprising an input/output (I/O) interface coupled to the memory buffer modules.

3. The memory subsystem of claim 1, wherein each of the plurality of memory cells includes a magnetic tunnel junction (MTJ) and a selection transistor coupled in series.

4. The memory subsystem of claim 1, wherein each of the plurality of memory cells includes a magnetic tunnel junction (MTJ) and a two-terminal selector coupled in series.

5. The memory subsystem of claim 1, wherein the memory subsystem is compliant with at least one version of double data rate synchronous dynamic random access memory (DDR SDRAM) specification.

6. The memory subsystem of claim 1, wherein number of the columns of the memory cells in each of the memory banks is same as number of the sense amplifiers in the sense amplifier module.

7. The memory subsystem of claim 1, wherein number of the bit-lines in in each of the memory banks is same as number of the sense amplifiers in the sense amplifier module.

8. The memory subsystem of claim 1, wherein number of the columns of the memory cells in each of the memory banks is twice as many as number of the sense amplifiers in the sense amplifier module.

9. The memory subsystem of claim 1, wherein number of the bit-lines in in each of the memory banks is twice as many as number of the sense amplifiers in the sense amplifier module.

10. The memory subsystem of claim 1, wherein number of the sense amplifiers in the sense amplifier module is same as number of the memory buffers in each of the memory buffer modules.

11. The memory subsystem of claim 10, wherein each of the memory buffers in each of the memory buffer modules is made of a flip-flop or latch.

12. A memory subsystem comprising:
a plurality of memory banks, each of the memory banks including a plurality of memory cells arranged in rows and columns with word-lines connecting to the memory cells along a row direction and bit-lines connecting to the memory cells along a column direction;
a sense amplifier module shared by the plurality of memory banks, the sense amplifier module including an error correction code (ECC) decoder and a plurality of sense amplifiers for sensing resistance of the memory cells;
a post processor coupled to the sense amplifier module for further processing of decoded data from the sense amplifier module; and
a plurality of memory buffer modules coupled to the post processor, each of the memory buffer modules including a plurality of memory buffers for storing data from the sense amplifiers.

13. The memory subsystem of claim 12 further comprising another sense amplifier module shared by the plurality of memory blocks, the another sense amplifier module including another error correction code (ECC) decoder and another plurality of sense amplifiers for sensing resistance of the memory cells.

14. The memory subsystem of claim 12, wherein the post processor includes a digital signal processor and majority voting functionality.

15. The memory subsystem of claim 12, wherein each of the plurality of memory cells includes a magnetic tunnel junction (MTJ) and a selection transistor coupled in series.

16. The memory subsystem of claim 12, wherein each of the plurality of memory cells includes a magnetic tunnel junction (MTJ) and a two-terminal selector coupled in series.

17. The memory subsystem of claim 12, wherein the memory subsystem is compliant with at least one version of double data rate synchronous dynamic random access memory (DDR SDRAM) specification.

18. The memory subsystem of claim 12, wherein number of the sense amplifiers in the sense amplifier module is same as number of the memory buffers in each of the memory buffer modules.

19. The memory subsystem of claim 12, wherein number of the columns of the memory cells in each of the memory banks is same as number of the sense amplifiers in the sense amplifier module.

20. The memory subsystem of claim 12, wherein number of the bit-lines in each of the memory banks is twice as many as number of the sense amplifiers in the sense amplifier module.
